(19) United States
(12) Patent Application Publication
(10) Pub. No.: US 2026/0136799 A1
(43) Pub. Date: May 14, 2026

(54) Electoluminescent Display Device

(71) Applicant: LG Display Co., Ltd., Seoul (KR)

(72) Inventor: Boseong Kim, Paju-si (KR)

(21) Appl. No.: 19/322,162

(22) Filed: Sep. 8, 2025

(30) Foreign Application Priority Data
Nov. 14, 2024 (KR) 10-2024-0161931

(51) Int. Cl. H10K 59/38; H10K 59/80

(52) U.S. Cl. CPC H10K 59/38; H10K 59/8792

(57) ABSTRACT

An electroluminescent display device is provided, a substrate including a first sub-pixel, a second sub-pixel, and a third sub-pixel, a first electrode disposed in each of the first sub-pixel, the second sub-pixel, and the third sub-pixel on the substrate, a light emitting layer including a first light emitting layer on the first electrode of the first sub-pixel, a second light emitting layer on the first electrode of the second sub-pixel, and a third light emitting layer on the first electrode of the third sub-pixel, a second electrode disposed on the light emitting layer, and a color filter disposed on the second electrode, wherein the color filter includes a first color filter overlapping the first sub-pixel, the second sub-pixel, and a boundary area between the first sub-pixel and the second sub-pixel, and a second color filter overlapping the third sub-pixel.

### CROSS-REFERENCE TO RELATED APPLICATIONS

This application claims the benefit of the Republic of Korea Patent Application No. 10-2024-0161931 filed on November 14, 2024, each of which is hereby incorporated by reference in its entirety.

### BACKGROUND

### Field of Technology

The present disclosure relates to an electroluminescent display device.

### DESCRIPTION OF THE RELATED ART

The electroluminescent display device includes a first electrode, a second electrode, and a light emitting layer disposed between the first electrode and the second electrode, and displays an image by emitting the light emitting layer by an electric field between the first electrode and the second electrode.

The electroluminescent display device may include a red sub-pixel, a green sub-pixel, and a blue sub-pixel to display images of various colors.

To this end, a red color filter is disposed in the red sub-pixel, a green color filter is disposed in the green sub-pixel, a blue color filter is disposed in the blue sub-pixel, and a light blocking layer is disposed at a boundary between adjacent sub-pixels to prevent light of different colors from being mixed between adjacent sub-pixels.

However, in the above conventional structure, luminance decreases according to a viewing angle. In other words, in the conventional structure, when a user views an image from a side, an amount of emitted light is reduced because light may be blocked by the light blocking layer, and thus luminance decreases.

### SUMMARY

The present disclosure has been made in view of the above problems and it is an aspect of the present disclosure to provide an electroluminescent display device that can reduce a problem of decreasing luminance depending on a viewing angle.

In accordance with an aspect of the present disclosure, the above and other technical effects can be accomplished by the provision of an electroluminescent display device comprising a substrate including a first sub-pixel, a second sub-pixel, and a third sub-pixel, a first electrode disposed in each of the first sub-pixel, the second sub-pixel, and the third sub-pixel on the substrate, a light emitting layer including a first light emitting layer on the first electrode of the first sub-pixel, a second light emitting layer on the first electrode of the second sub-pixel, and a third light emitting layer on the first electrode of the third sub-pixel, a second electrode disposed on the light emitting layer, and a color filter disposed on the second electrode, wherein the color filter includes a first color filter overlapping the first sub-pixel, the second sub-pixel, and a boundary area between the first sub-pixel and the second sub-pixel, and a second color filter overlapping the third sub-pixel.

In addition, in accordance with an aspect of the present disclosure, the above and other technical effects can be accomplished by the provision of an electroluminescent display device comprising a first light emitting area emitting light of a first color, a second light emitting area emitting light of a second color, a third light emitting area emitting light of a third color, a first color filter overlapping the first light emitting area, the second light emitting area, and a boundary area between the first light emitting area and the second light emitting area, and a second color filter overlapping the third light emitting area.

In still another embodiment, an electroluminescent display device comprises a first light emitting device configured to emit first color light; a second light-emitting device configured to emit second color light; a third light-emitting device configured to emit third color light; a first bank between the first light-emitting device and the second light-emitting device; a second bank between the first light-emitting device and the third light-emitting device; a third bank between the second light-emitting device and the third light-emitting device; a first color filter configured to transmit the first color light and the second color light but absorb the third color light; and a second color filter configured to transmit the third color light but absorb the first color light and the second color light. The first color filter may overlap the entire first light-emitting device, the entire second light-emitting device, the entire first bank, a first portion of the second bank, and a first portion of the third bank, in a plan view. The electroluminescent display device may further comprise a light blocking layer disposed between the first color filter and the second color filter, the light blocking layer overlapping a second portion of the second bank and a second portion of the third bank but not overlapping the first bank, in a plan view. The second color filter overlaps the entire third light-emitting device, a third portion of the second bank, and a third portion of the third bank, in a plan view.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a schematic cross-sectional view of an electroluminescent display device according to an embodiment of the present disclosure.

FIG. 2 is a schematic plan view of an electroluminescent display device according to an embodiment of the present disclosure.

FIG. 3A is a graph showing a light emission spectrum of a green sub-pixel and a red sub-pixel and a transmission spectrum of a yellow color filter according to an embodiment of the present disclosure.

FIG. 3B is a graph showing a light emission spectrum of a blue sub-pixel and a transmission spectrum of a yellow color filter according to an embodiment of the present disclosure.

FIG. 3C is a graph showing a state in which a color coordinates of light emitted from a blue sub-pixel are changed according to FIG. 3B.

FIG. 4 is a schematic cross-sectional view of an electroluminescent display device according to another embodiment of the present disclosure.

FIG. 5 is a schematic plan view of an electroluminescent display device according to another embodiment of the present disclosure.

FIG. 6A is a graph showing a light emission spectrum of a blue sub-pixel and a green sub-pixel and a transmission spectrum of a cyan color filter according to another embodiment of the present disclosure.

FIG. 6B is a graph showing a light emission spectrum of a red sub-pixel and a transmission spectrum of a cyan color filter according to another embodiment of the present disclosure.

FIG. 6C is a graph showing a state in which a color coordinate of light emitted from a red sub-pixel is changed according to FIG. 6B.

FIG. 7 is a schematic cross-sectional view of an electroluminescent display device according to another embodiment of the present disclosure.

FIG. 8 is a schematic plan view of an electroluminescent display device according to another embodiment of the present disclosure.

FIG. 9A is a graph showing a light emission spectrum of a blue sub-pixel and a red sub-pixel and a transmission spectrum of a magenta color filter according to another embodiment of the present disclosure.

FIG. 9B is a graph showing a light emission spectrum of a green sub-pixel and a transmission spectrum of a magenta color filter according to another embodiment of the present disclosure.

FIG. 9C is a graph showing a state in which a color coordinate of light emitted from a green sub-pixel is changed according to FIG. 9B.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only~’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon~’, ‘above~’, ‘below~’ and ‘next to~’, one or more portions may be disposed between two other portions unless ‘just’ or ‘direct’ is used. The terms, such as “below,” “lower,” “above,” “upper” and the like, may be used herein to describe a relationship between element (s) as illustrated in the drawings. It will be understood that the terms are spatially relative and based on the orientation depicted in the drawings.

A description of a time relationship may include a case in which the temporal precedence relationship is described as "after", "following", or "before", etc., and is not continuous unless "right away" or "directly", is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be "connected," "coupled," "connected," or "attached" to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be "in contact" or "overlapping" with another component or layer, the component or layer may be in direct contact or overlapping with another component or layer, but other components may be interposed between each component that may be indirectly in contact or overlapping without particular explicit description.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

"First direction", "second direction", "third direction", "X-axis direction", "Y-axis direction", and "Z-axis direction" should not be interpreted only as a geometric relationship perpendicular to each other, but may mean that the configuration of the present disclosure has a wider direction within a range in which the configuration of the present disclosure may functionally act.

Features of each of the various embodiments of the present specification may be partially or entirely coupled or combined with each other, technically various interworking and driving are possible, and each of the embodiments may be independently implemented with respect to each other or may be implemented together in a related relationship.

Hereinafter, one embodiment of the present disclosure will be described in detail with reference to the accompanying drawings.

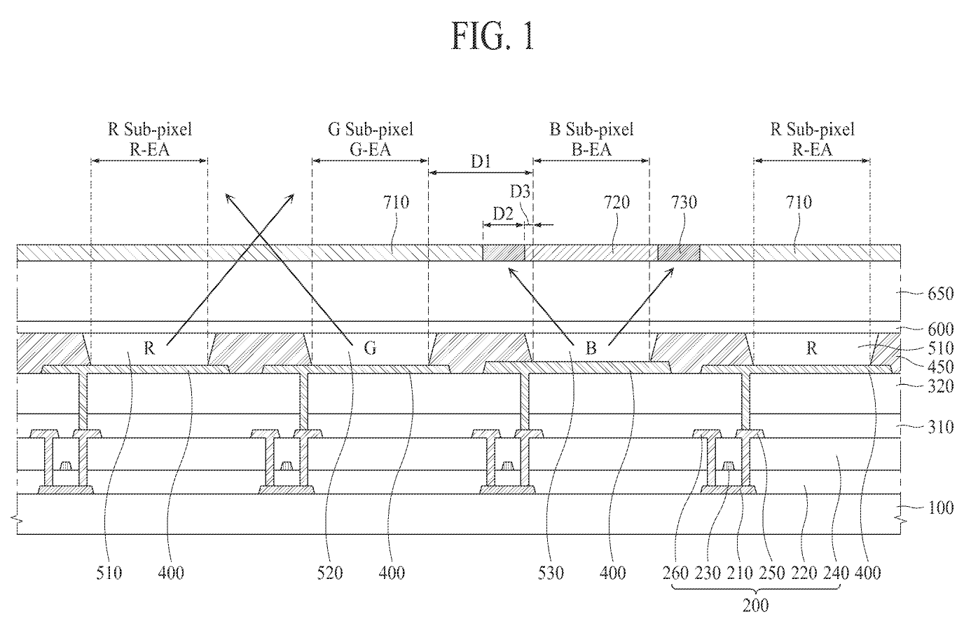

FIG. 1 is a schematic cross-sectional view of an electroluminescent display device according to an embodiment of the present disclosure.

As shown in FIG. 1, the electroluminescent display device according to an embodiment of the present disclosure includes a substrate 100, a circuit element layer 200, a passivation layer 310, a planarization layer 320, a first electrode 400, a bank 450, a light emitting layer 510, 520, 530, a second electrode 600, an encapsulation layer 650, color filters 710 and 720, and a light blocking layer 730.

The substrate 100 may be made of glass, plastic, or semiconductor material, but is not limited thereto. The electroluminescent display device according to an embodiment of the present disclosure may be made of a top emission type, and accordingly, not only a transparent material but also an opaque material may be used as a material of the substrate 100.

The circuit element layer 200 is disposed on the substrate 100.

The circuit element layer 200 includes a driving thin film transistor disposed for each of a red sub-pixel (R sub-pixel), a green sub-pixel (G sub-pixel), and a blue sub-pixel (B sub-pixel).

An electroluminescent display device according to an embodiment of the present disclosure includes a plurality of sub-pixels including the red sub-pixel (R sub-pixel), the green sub-pixel (G sub-pixel), and the blue sub-pixel (B sub-pixel). One pixel may be formed by a combination of the red sub-pixel (R sub-pixel), the green sub-pixel (G sub-pixel), and the blue sub-pixel (B sub-pixel), but is not limited thereto. For convenience, FIG. 1 shows two red sub-pixels.

The driving thin film transistor includes an active layer 210 disposed on the substrate 100, a gate insulating layer 220 disposed on the active layer 210, a gate electrode 230 disposed on the gate insulating layer 220, an interlayer insulating layer 240 disposed on the gate electrode 230, and a source electrode 250 and a drain electrode 260 disposed on the interlayer insulating layer 240. The source electrode 250 and the drain electrode 260 are connected to one side and the other side of the active layer 210 through holes disposed in the interlayer insulating layer 240 and the gate insulating layer 220.

Although the driving thin film transistor having a top gate structure in which the gate electrode 230 is disposed on the active layer 210 is illustrated in the drawing, the present disclosure may include a driving thin film transistor having a bottom gate structure in which the gate electrode 230 is disposed under the active layer 210. In addition, although the gate insulating layer 220 is formed on an entire surface of the substrate 100, the gate insulating layer 220 may be patterned in the same manner as the gate electrode 230 under the gate electrode 230. The driving thin film transistor may be changed into various forms known in the art.

Although not shown, the circuit element layer 200 may further include various signal lines including gate line, data line, power line, and reference line, various thin film transistors including switching thin film transistors and sensing thin film transistors, and capacitors.

The switching thin film transistor is switched according to a gate signal supplied to the gate line to supply a data voltage supplied from the data line to the driving thin film transistor.

The driving thin film transistor is switched according to the data voltage supplied from the switching thin film transistor to generate a data current from a power source supplied from the power line and supply the data current to the first electrode 400.

The sensing thin film transistor may sense a threshold voltage deviation of the driving thin film transistor, which causes image quality deterioration, and supplies a current of the driving thin film transistor to the reference line in response to a sensing control signal supplied from the gate line or a separate sensing line.

The capacitor may maintain the data voltage supplied to the driving thin film transistor for one frame, and be connected to a gate terminal and a source terminal of the driving thin film transistor, respectively.

The passivation layer 310 is disposed on the circuit element layer 200. Specifically, the passivation layer 310 is disposed on the source electrode 250 and the drain electrode 260. The passivation layer 310 may be formed of an inorganic insulating material, but is not limited thereto.

The planarization layer 320 is disposed on the passivation layer 310. The planarization layer 320 may be made of an organic insulating material.

The passivation layer 310 and the planarization layer 320 include a contact hole, and the source electrode 250 may be exposed through the contact hole, and the first electrode 400 may be connected to the source electrode 250 exposed through the contact hole. In some cases, the drain electrode 260 may be exposed through the contact hole disposed in the passivation layer 310 and the planarization layer 320, and the first electrode 400 may be connected to the drain electrode 260 exposed through the contact hole.

The first electrode 400 is disposed in each of the red sub-pixel (R sub-pixel), the green sub-pixel (G sub-pixel), and the blue sub-pixel (B sub-pixel) on the planarization layer 320.

The first electrode 400 is connected to the source electrode 250 or the drain electrode 260 through the contact hole disposed in the passivation layer 310 and the planarization layer 320.

The electroluminescent display device according to an embodiment of the present disclosure may be formed by the top emission type, and accordingly, the first electrode 400 may include a reflective electrode.

The bank 450 is disposed on the planarization layer 320, and is formed at a boundary between the red sub-pixel (R sub-pixel), the green sub-pixel (G sub-pixel), and the blue sub-pixel (B sub-pixel).

The bank 450 is disposed on the first electrode 400 to cover an edge of the first electrode 400. Light emitting areas R-EA, G-EA, and B-EZ may be defined by the bank 450. Specifically, portions of the first electrode 400 exposed without being covered by the bank 450 may become light emitting areas R-EA, G-EA, and B-EA. Accordingly, a red light emitting area R-EA may be disposed in the red sub-pixel, a green light emitting area G-EA may be disposed in the green sub-pixel, and a blue light emitting area B-EA may be disposed in the blue sub-pixel B sub-pixel.

The light emitting layers 510, 520, and 530 are disposed in the light emitting areas R-EA, G-EA, and B-EA defined by the bank 450. The light emitting layers 510, 520, and 530 are disposed on the first electrode 400, particularly, on a portion of the first electrode 400 exposed without being covered by the bank 450.

The first light emitting layer 510 emitting red (R) light is disposed in the red light emitting area R-EA, the second light emitting layer 520 emitting green (G) light is disposed in the green light emitting area G-EA, and the third light emitting layer 530 emitting blue (B) light is disposed in the blue light emitting area B-EA.

In some cases, some of the light emitting layers 510, 520, and 530 may extend to an upper surface of the bank 450 while contacting a side surface of the bank 450.

The second electrode 600 is disposed on the light emitting layers 510, 520, and 530 and the bank 450. The second electrode 600 may be in contact with the light emitting layers 510, 520, and 530 and the bank 450. The second electrode 600 may be continuous without being disconnected between all sub-pixels (R sub-pixel, G sub-pixel, and B sub-pixel)

The electroluminescent display device according to an embodiment of the present disclosure may be configured by the top emission type, and thus the second electrode 600 may include a transparent electrode or a translucent electrode.

The encapsulation layer 650 is disposed on the second electrode 600.

The encapsulation layer 650 may have a three-layer structure of a first inorganic insulating layer, an organic insulating layer disposed on the first inorganic insulating layer, and a second inorganic insulating layer disposed on the organic insulating layer. The encapsulation layer 650 may be continuous without being disconnected between all sub-pixels (R sub-pixel, G sub-pixel, and B sub-pixel).

The color filters 710 and 720 are disposed on the encapsulation layer 650.

The color filters 710 and 720 include a first color filter 710 and a second color filter 720.

The first color filter 710 may be formed of a yellow color filter. The first color filter 710 may transmit red (R) light and green (G) light and absorb blue (B) light. For example, the first color filter 710 may absorb blue (B) light in a range of 380 nm to 500 nm.

The first color filter 710 may overlap the red sub-pixel (R sub-pixel) and the green sub-pixel (G sub-pixel). The first color filter 710 may overlap an entire area of the red sub-pixel (R sub-pixel) and an entire area of the green sub-pixel (G sub-pixel). The first color filter 710 may overlap the red light emitting area R-EA and the green light emitting area G-EA. The first color filter 710 may overlap the entire red light emitting area R-EA and the entire green light emitting area G-EA.

Accordingly, red (R) light emitted from the first light emitting layer 510 of the red light emitting area R-EA may pass through the first color filter 710, and thus red (R) light may be emitted from the red sub-pixel (R sub-pixel). In addition, green (G) light emitted from the second light emitting layer 520 of the green light emitting area G-EA may pass through the first color filter 710, and thus green (G) light may be emitted from the green sub-pixel (G sub-pixel).

The first color filter 710 may overlap a boundary area between the red sub-pixel (R sub-pixel) and the green sub-pixel (G sub-pixel). The first color filter 710 may overlap the entire boundary area between boundary area between the red sub-pixel (R sub-pixel) and the green sub-pixel (G sub-pixel). The first color filter 710 may overlap a boundary area between the red light emitting area R-EA and the green light emitting area G-EA. The first color filter 710 may overlap the entire boundary area between the red light emitting area R-EA and the green light emitting area G-EA. The first color filter 710 may overlap the entire area of the bank 450 disposed in the boundary area between the red light emitting area R-EA and the green light emitting area G-EA.

Accordingly, the red (R) light emitted from the first light emitting layer 510 of the red light emitting area R-EA may be emitted to the boundary area between the red sub-pixel (R sub-pixel) and the green sub-pixel (G sub-pixel), and the green (G) light emitted from the second light emitting layer 520 of the green light emitting area G-EA may be emitted to the boundary area between the red sub-pixel (R sub-pixel) and the green sub-pixel (G sub-pixel), and thus luminance characteristics according to a viewing angle may be improved.

In addition, the first color filter 710 may overlap a portion of a boundary area between the red sub-pixel (R sub-pixel) and the blue sub-pixel (B sub-pixel). The first color filter 710 may overlap a portion of a boundary area between the red light emitting area R-EA and the blue light emitting area B-EA. The first color filter 710 may overlap a portion of the bank 450 disposed at a boundary area between the red light emitting area R-EA and the blue light emitting area B-EA. Accordingly, red light R emitted from the first light emitting layer 510 of the red light emitting area R-EA may also be emitted to the boundary area between the red sub-pixel (R sub-pixel) and the blue sub-pixel (B sub-pixel), and thus luminance characteristics according to the viewing angle may be improved.

In addition, the first color filter 710 may overlap a portion of a boundary area between the green sub-pixel (G sub-pixel) and the blue sub-pixel (B sub-pixel). The first color filter 710 may overlap a portion of a boundary area between the green light emitting area G-EA and the blue light emitting area B-EA. The first color filter 710 may overlap a portion of the bank 450 disposed at a boundary area between the green light emitting area G-EA and the blue light emitting area B-EA. Accordingly, green light G emitted from the second light emitting layer 520 of the green light emitting area G-EA may also be emitted to the boundary area between the green sub-pixel (G sub-pixel) and the blue sub-pixel (B sub-pixel), and thus luminance characteristics according to the viewing angle may be improved.

The second color filter 720 may be formed of a blue color filter. The second color filter 720 absorbs red (R) light and green (G) light and transmits blue (B) light.

The second color filter 720 may overlap the blue sub-pixel (B sub-pixel). The second color filter 720 may overlap the entire area of the blue sub-pixel (B sub-pixel). The second color filter 720 may overlap the blue light emitting area B-EA. The second color filter 720 may overlap the entire area of the blue light emitting area B-EA. Accordingly, blue (B) light emitted from the third light emitting layer 530 of the blue light emitting area B-EA may pass through the second color filter 720, and thus blue (B) light may be emitted from the blue sub-pixel (B sub-pixel).

The light blocking layer 730 is disposed on the encapsulation layer 650.

The light blocking layer 730 is disposed in an area between the first color filter 710 and the second color filter 720.

The light blocking layer 730 may overlap a portion of a boundary area between the red sub-pixel (R sub-pixel) and the blue sub-pixel (B sub-pixel), and may overlap a portion of a boundary area between the green sub-pixel (G sub-pixel) and the blue sub-pixel (B sub-pixel). The light blocking layer 730 may overlap a portion of a boundary area between the red light emitting area R-EA and the blue light emitting area B-EA, and may overlap a portion of a boundary area between the green light emitting area G-EA and the blue light emitting area B-EA.

Accordingly, the light blocking layer 730 may block blue (B) light emitted from the third light emitting layer 530 of the blue light emitting area (B-EA) from being emitted to the red sub-pixel (R sub-pixel) or the green sub-pixel (G sub-pixel). In addition, the light blocking layer 730 may block red (R) light emitted from the first light emitting layer 510 in the red light emitting area R-EA and green (G) light emitted from the second light emitting layer 520 in the green light emitting area G-EA from being emitted to the blue sub-pixel (B sub-pixel).

In some cases, the light blocking layer 730 may overlap at least one of the first color filter 710 and the second color filter 720. For example, the light blocking layer 730 may be in contact with a part of a lower surface or a part of an upper surface of at least one of the first color filter 710 and the second color filter 720.

Meanwhile, a width D2 of the light blocking layer 730 may be less than a distance D1 between adjacent sub-pixels (R sub-pixel, G sub-pixel, and B sub-pixel).

In this case, a distance D3 between one end of the light blocking layer 730 and one end of the sub-pixel (R sub-pixel, G sub-pixel, and B sub-pixel) facing the light blocking layer 730 may be changed according to a distance between the light emitting layers 510, 520, and 530 and the color filters 710 and 720.

For example, when the distance between the light emitting layers 510, 520, and 530 and the color filters 710 and 720 is 10 μm, a minimum value of the distance D3, which is not influential at a 45 degree viewing angle, may be 10 μm. If the distance between the light emitting layers 510, 520, and 530 and the color filters 710 and 720 is reduced, the value of the distance D3, which is not influential at a 45 degree viewing angle, is also decreased. And, if the distance between the light emitting layers 510, 520, and 530 and the color filters 710 and 720 is increased, the value of the distance D3, which is not influential at a 45 degree viewing angle, is also increased.

A maximum value of the width D2 of the light blocking layer 730 may be [D1 - (2×D3)], and a minimum value of the width D2 of the light blocking layer 730 may be 1μm, but is not limited thereto. The same applies to other embodiments below.

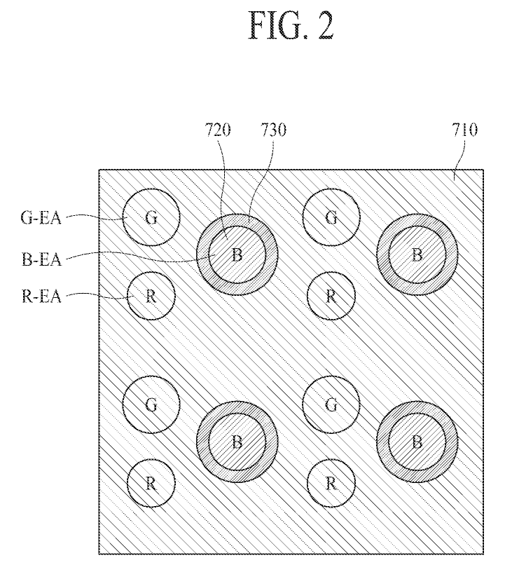

FIG. 2 is a schematic plan view of an electroluminescent display device according to an embodiment of the present disclosure.

As shown in FIG. 2, each of the red light emitting area R-EA, the green light emitting area G-EA, and the blue light emitting area B-EA may have a circular structure. However, the present disclosure is not limited thereto, and each of the red light emitting area R-EA, the green light emitting area G-EA, and the blue light emitting area B-EA may be variously changed to a rectangle, a square, a rhombus, a pentagon, or a hexagon.

The blue light emitting area B-EA is surrounded by the light blocking layer 730. An outer periphery of the light blocking layer 730 has a shape corresponding to an outer periphery of the blue light emitting area B-EA. When the outer periphery of the blue light emitting area B-EA has a circular structure, the outer periphery of the light blocking layer 730 may also have a circular structure, and accordingly, the light blocking layer 730 may have a donut structure. An inner surface of the light blocking layer 730 may contact the outer periphery of the blue light emitting area B-EA.

In addition, the outer periphery of the light blocking layer 730 may not be in contact with the red light emitting area R-EA and the green light emitting area G-EA. The outer periphery of the light blocking layer 730 may be spaced apart from an outer periphery of the red light emitting area R-EA and an outer periphery of the green light emitting area G-EA by a predetermined distance.

The first color filter 710 may overlap the entire red light emitting area R-EA, the entire green light emitting area G-EA, the entire boundary area between the red light emitting area R-EA and the green light emitting area G-EA, a portion of the boundary area between the red light emitting area R-EA and the blue light emitting area B-EA, and a portion of the boundary area between the green light emitting area G-EA and the blue light emitting area B-EA. The first color filter 710 transmits red (R) light and green (G) light and absorbs blue (B) light.

The second color filter 720 may overlap the entire area of the blue light emitting area B-EA. The second color filter 720 absorbs red (R) light and green (G) light and transmits blue (B) light.

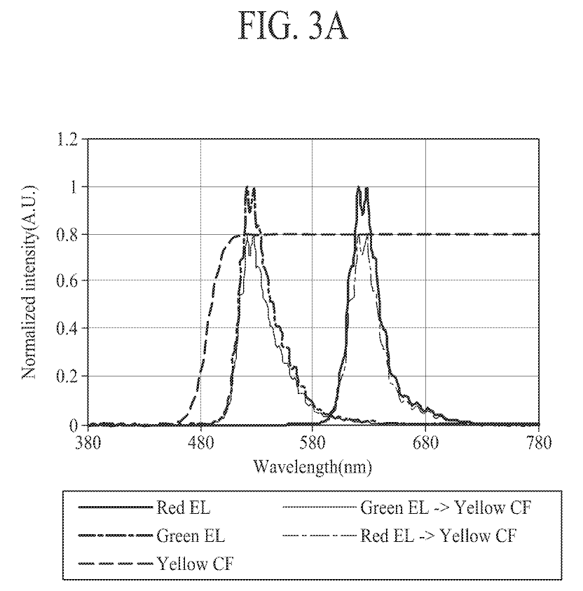

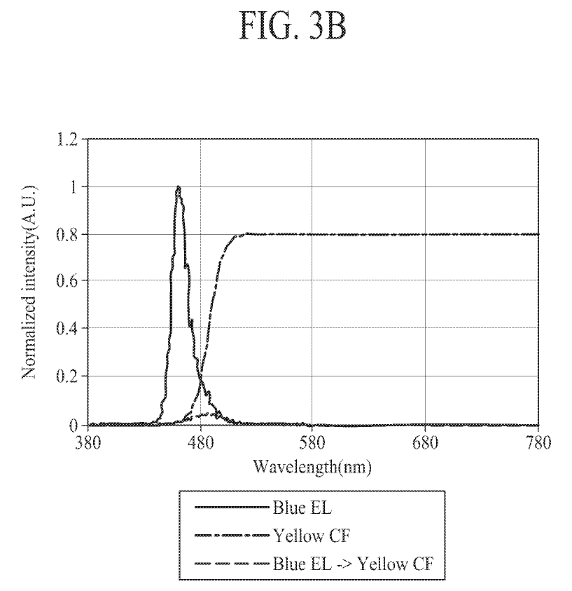

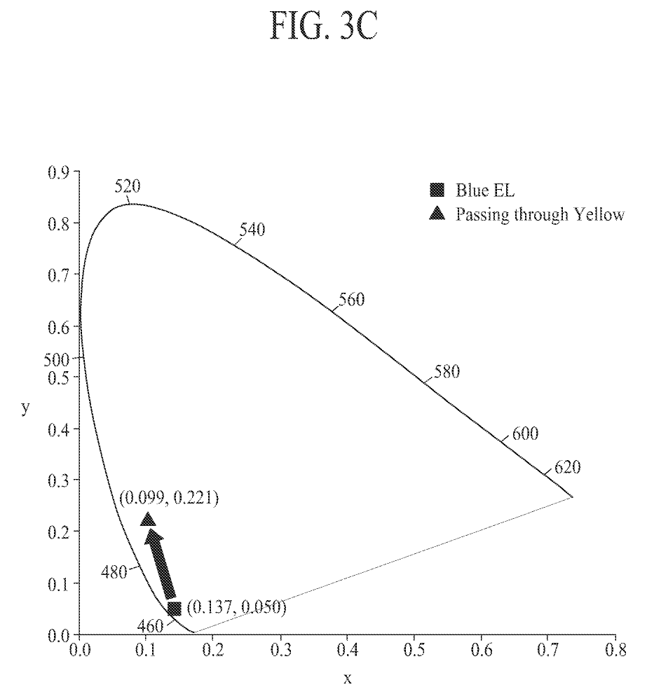

FIG. 3A is a graph showing a light emission spectrum of a green sub-pixel and a red sub-pixel and a transmission spectrum of a yellow color filter according to an embodiment of the present disclosure, FIG. 3B is a graph showing a light emission spectrum of a blue sub-pixel and a transmission spectrum of a yellow color filter according to an embodiment of the present disclosure, and FIG. 3C is a graph showing a state in which a color coordinates of light emitted from a blue sub-pixel are changed according to FIG. 3B.

As can be seen from FIG. 3A, the green light emitted from the green sub-pixel and the red light emitted from the red sub-pixel pass through the yellow color filter. However, since an intensity of a peak of the light transmitted by the yellow color filter is smaller than an intensity of a peak of the green light emitted from the green sub-pixel and an intensity of a peak of the red light emitted from the red sub-pixel, an intensity of a peak of the green light and the red light may be slightly reduced after passing through the yellow color filter.

As shown in FIG. 3B, most of the blue light emitted from the blue sub-pixel is absorbed by the yellow color filter, but some of the blue light can pass through the yellow color filter. And, as shown in FIG. 3C, a color coordinate of some of the blue light passing through the yellow color filter can be shifted from an original first color coordinate (Blue EL) to a second color coordinate (passing through yellow) which is different from the first color coordinate (Blue EL).

Therefore, in FIGS. 1 and 2 described above, if the light blocking layer 730 is not disposed and the first color filter 710 is filled in an area of the light blocking layer 730, the blue light emitted from the blue sub-pixel (B Sub-pixel) passes through the first color filter 710 and the color coordinates are shifted, which can reduce image quality, so it may not be desirable for the first color filter 710 to fill the area of the light blocking layer 730.

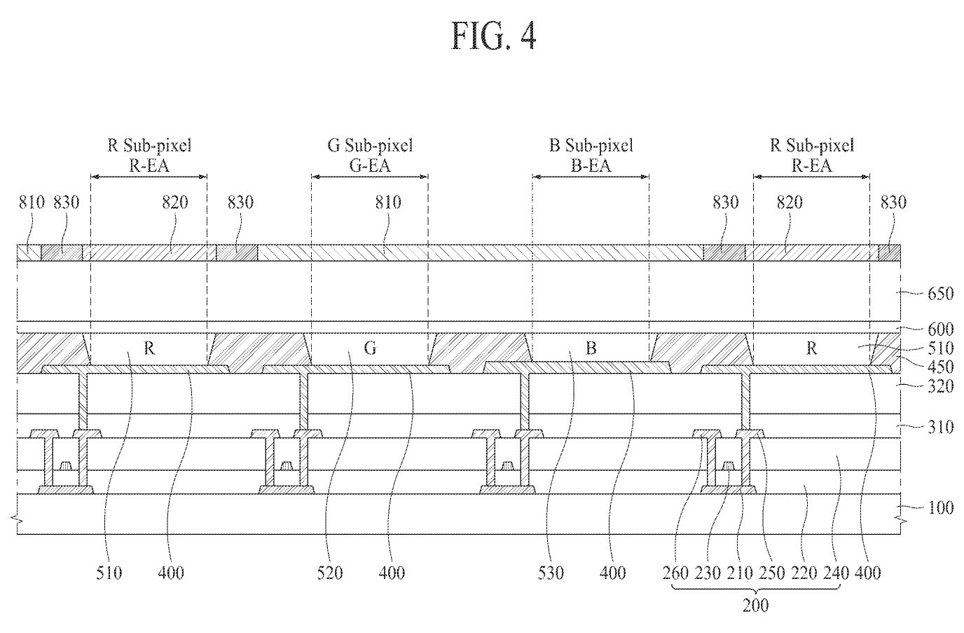

FIG. 4 is a schematic cross-sectional view of an electroluminescent display device according to another embodiment of the present disclosure. FIG. 4 is the same as FIG. 1 described above except for configurations of color filters 810 and 820 and a light blocking layer 830. Accordingly, the same reference numerals are assigned to the same configurations, and hereinafter, only different configurations will be described.

As shown in FIG. 4, the color filters 810 and 820 are disposed on the encapsulation layer 650.

The color filters 810 and 820 include a first color filter 810 and a second color filter 820.

The first color filter 810 may be formed of a cyan color filter. The first color filter 810 may transmit green (G) light and blue (B) light and absorb red (R) light. For example, the first color filter 810 may absorb red (R) light in a range of 600 nm to 780 nm.

The first color filter 810 may overlap a blue sub-pixel (B sub-pixel) and a green sub-pixel (G sub-pixel). The first color filter 810 may overlap an entire area of the blue sub-pixel (B sub-pixel) and an entire area of the green sub-pixel (G sub-pixel). The first color filter 810 may overlap a blue light emitting area B-EA and a green light emitting area G-EA. The first color filter 810 may overlap the entire blue light emitting area B-EA and the entire green light emitting area G-EA.

Accordingly, blue (B) light emitted from the third light emitting layer 530 in the blue light emitting area B-EA may pass through the first color filter 810, and thus blue (B) light may be emitted from the blue sub-pixel (B sub-pixel). Furthermore, green (G) light emitted from the second light emitting layer 520 in the green light emitting area G-EA may pass through the first color filter 810, so that green (G) light may be emitted from the green sub-pixel (G sub-pixel).

The first color filter 810 may overlap a boundary area between the blue sub-pixel (B sub-pixel) and the green sub-pixel (G sub-pixel). The first color filter 810 may overlap the entire boundary area between the blue sub-pixel (B sub-pixel) and the green sub-pixel (G sub-pixel). The first color filter 810 may overlap the boundary area between the blue light emitting area B-EA and the green light emitting area G-EA. The first color filter 810 may overlap the entire boundary area between the blue light emitting area B-EA and the green light emitting area G-EA. The first color filter 810 may overlap an entire area of the bank 450 disposed in the boundary area between the blue light emitting area B-EA and the green light emitting area G-EA.

Accordingly, the blue (B) light emitted from the third light emitting layer 530 of the blue light emitting area B-EA may be emitted to the boundary area between the blue sub-pixel (B sub-pixel) and the green sub-pixel (G sub-pixel), and the green (G) light emitted from the second light emitting layer 520 of the green light emitting area G-EA may be emitted to the boundary area between the blue sub-pixel (B sub-pixel) and the green sub-pixel (G sub-pixel), and thus luminance characteristics according to the viewing angle may be improved.

In addition, the first color filter 810 may overlap a portion of a boundary area between the red sub-pixel (R sub-pixel) and the blue sub-pixel (B sub-pixel). The first color filter 810 may overlap a portion of a boundary area between the red light emitting area R-EA and the blue light emitting area B-EA. The first color filter 810 may overlap a portion of the bank 450 disposed in a boundary area between the red light emitting area R-EA and the blue light emitting area B-EA. Accordingly, red (R) light emitted from the first light emitting layer 510 of the red light emitting area R-EA may also be emitted to a boundary area between a red sub-pixel (R sub-pixel) and the blue sub-pixel (B sub-pixel), and thus luminance characteristics according to the viewing angle may be improved.

In addition, the first color filter 810 may overlap a portion of a boundary area between the green sub-pixel (G sub-pixel) and the red sub-pixel (R sub-pixel). The first color filter 810 may overlap a portion of a boundary area between the green light emitting area G-EA and the red light emitting area R-EA. The first color filter 810 may overlap a portion of the bank 450 disposed in a boundary area between the green light emitting area G-EA and the red light emitting area R-EA. Accordingly, green (G) light emitted from the second light emitting layer 520 of the green light emitting area G-EA may also be emitted to a boundary area between the green sub-pixel (G sub-pixel) and the red sub-pixel (R sub-pixel), and thus luminance characteristics according to the viewing angle may be improved.

The second color filter 820 is formed of a red color filter. The second color filter 820 absorbs blue (B) light and green (G) light and transmits red (R) light.

The second color filter 820 may overlap the red sub-pixel (R sub-pixel). The second color filter 820 may overlap an entire area of the red sub-pixel (R sub-pixel). The second color filter 820 may overlap a red light emitting area (R-EA) The second color filter 820 may overlap an entire area of the red light emitting area (R-EA). Accordingly, red (R) light emitted from the first light emitting layer 510 of the red light emitting area (R-EA) may pass through the second color filter 820, and thus red (R) light may be emitted from the red sub-pixel (R sub-pixel).

The light blocking layer 830 is disposed in an area between the first color filter 810 and the second color filter 820.

The light blocking layer 830 may overlap a portion of a boundary area between the red sub-pixel (R sub-pixel) and the blue sub-pixel (B sub-pixel), and may overlap a portion of a boundary area between the green sub-pixel (G sub-pixel) and the blue sub-pixel (B sub-pixel). The light blocking layer 830 may overlap a portion of a boundary area between the red light emitting area R-EA and the blue light emitting area B-EA, and may overlap a portion of a boundary area between the green light emitting area G-EA and the blue light emitting area B-EA.

Accordingly, the light blocking layer 830 may block red (R) light emitted from the first light emitting layer 510 of the red light emitting area (R-EA) from being emitted to the blue sub-pixel (B sub-pixel) or the green sub-pixel (G sub-pixel). In addition, the light blocking layer 830 may block blue (B) light emitted from the third light emitting layer 530 in the blue light emitting area B-EA and green (G) light emitted from the second light emitting layer 520 in the green light emitting area G-EA from being emitted to the red sub-pixel (R sub-pixel).

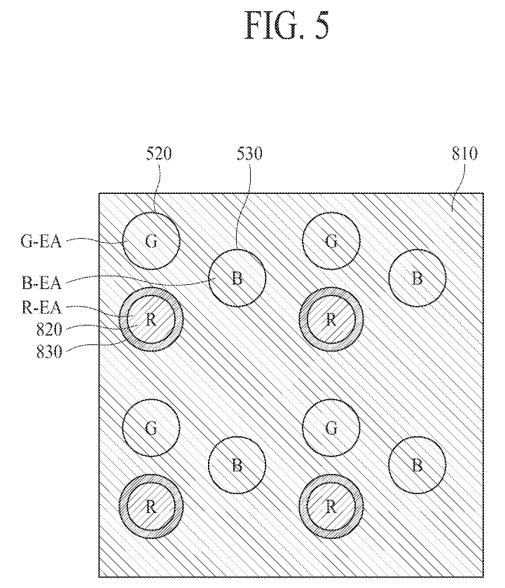

FIG. 5 is a schematic plan view of an electroluminescent display device according to another embodiment of the present disclosure. FIG. 5 is the same as FIG. 2 described above except for the configurations of the color filters 810 and 820 and the light blocking layer 830. Accordingly, the same reference numerals are assigned to the same configurations, and hereinafter, only different configurations will be described.

As shown in FIG. 5, the red light emitting area R-EA is surrounded by the light blocking layer 830. An outer periphery of the light blocking layer 830 has a shape corresponding to an outer periphery of the red light emitting area R-EA.

An inner surface of the light blocking layer 830 may be in contact with the outer periphery of the red light emitting area R-EA. In addition, the outer periphery of the light blocking layer 830 may not be in contact with the green light emitting area G-EA and the blue light emitting area B-EA. The outer periphery of the light blocking layer 830 may be spaced apart from an outer periphery of the blue light emitting area B-EA and an outer periphery of the green light emitting area G-EA by a predetermined distance.

The first color filter 810 may overlap the entire blue light emitting area B-EA, the entire green light emitting area G-EA, the entire boundary area between the blue light emitting area B-EA and the green light emitting area G-EA, a portion of the boundary area between the red light emitting area R-EA and the blue light emitting area B-EA, and a portion of the boundary area between the green light emitting area G-EA and the red light emitting area R-EA. The first color filter 810 transmits blue (B) light and green (G) light and absorbs red (R) light.

The second color filter 820 may overlap the entire area of the red light emitting area R-EA. The second color filter 820 absorbs blue (B) light and green (G) light and transmits red (R) light.

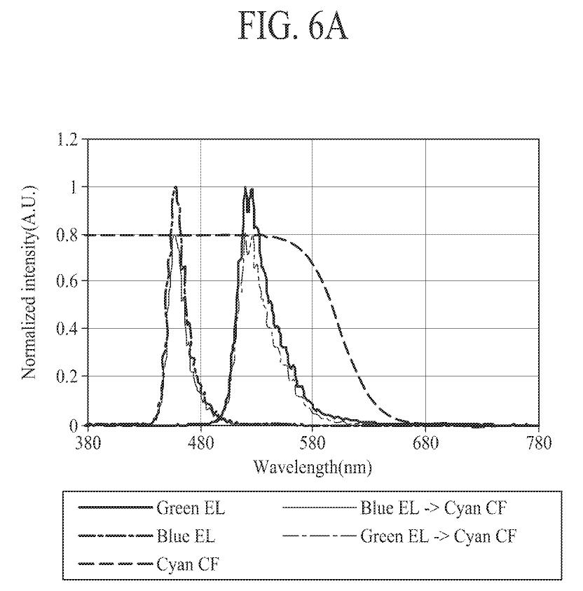

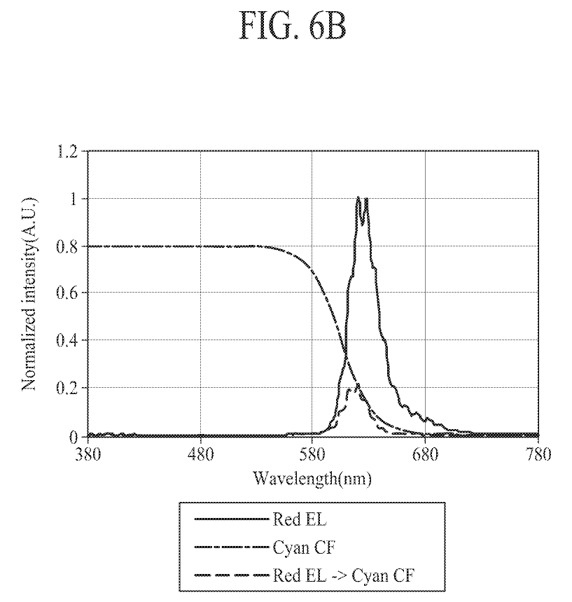

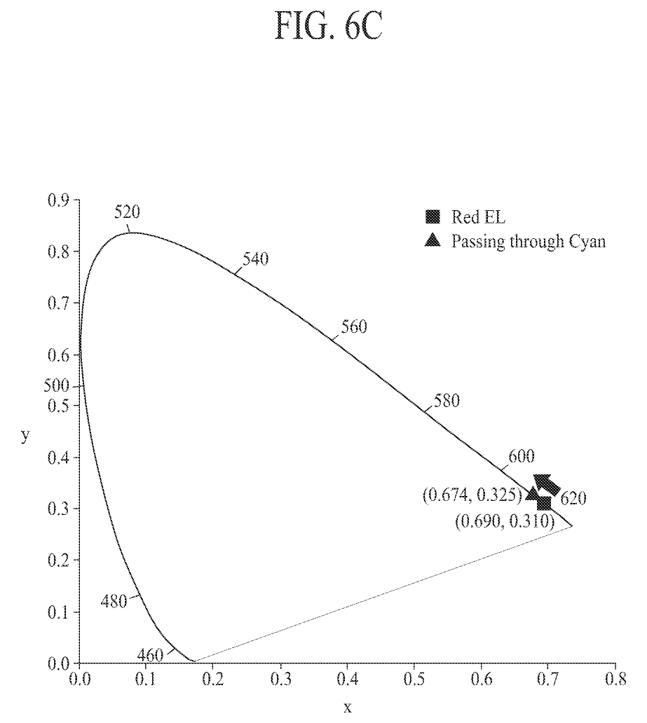

FIG. 6A is a graph showing a light emission spectrum of a blue sub-pixel and a green sub-pixel and a transmission spectrum of a cyan color filter according to another embodiment of the present disclosure, FIG. 6B is a graph showing a light emission spectrum of a red sub-pixel and a transmission spectrum of a cyan color filter according to another embodiment of the present disclosure, and FIG. 6C is a graph showing a state in which a color coordinate of light emitted from a red sub-pixel is changed according to FIG. 6B.

As can be seen from FIG. 6A the blue light emitted from the blue sub-pixel and the green light emitted from the green sub-pixel pass through a cyan color filter. However, since an intensity of a peak of the light transmitted by the cyan color filter is smaller than an intensity of a peak of the blue light emitted from the blue sub-pixel and an intensity of a peak of the green light emitted from the green sub-pixel, an intensity of a peak of the blue light and the green light may be slightly reduced after passing through the cyan color filter.

As shown in FIG. 6B, most of the red light emitted from the red sub-pixel is absorbed by the cyan color filter, but some of the red light can pass through the cyan color filter. And, as shown in FIG. 6C, a color coordinate of some of the red light passing through the cyan color filter can be shifted from an original first color coordinate (Red EL) to a second color coordinate (passing through cyan) which is different from the first color coordinate (Red EL).

Therefore, in FIGS. 4 and 5 described above, if the light blocking layer 830 is not disposed and the first color filter 810 is filled in an area of the light blocking layer 830, the red light emitted from the red sub-pixel (R Sub-pixel) passes through the first color filter 810 and the color coordinates are shifted, which can reduce image quality, so it may not be desirable for the first color filter 810 to fill the area of the light blocking layer 830.

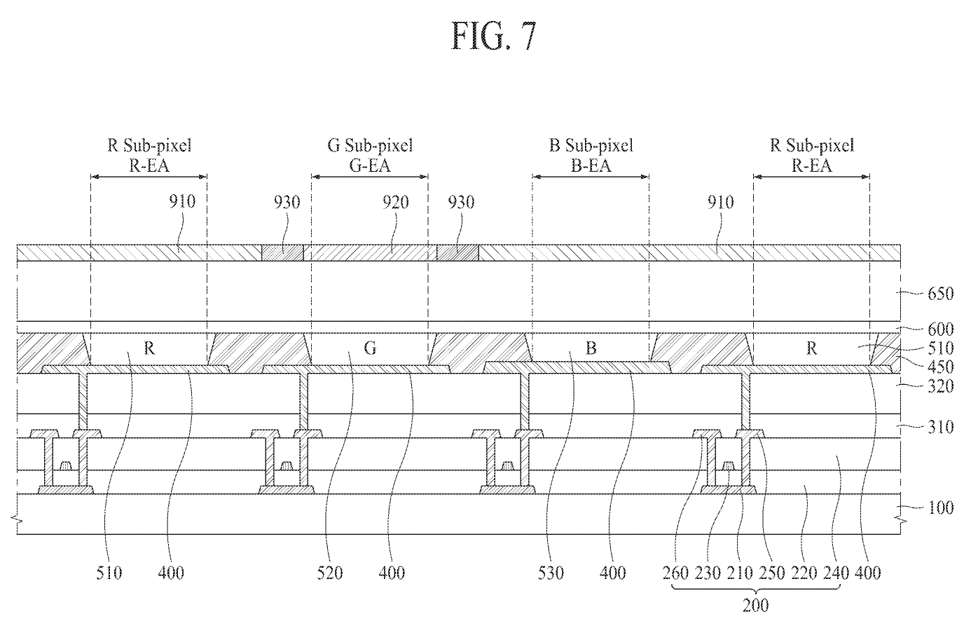

FIG. 7 is a schematic cross-sectional view of an electroluminescent display device according to another embodiment of the present disclosure. FIG. 7 is the same as FIG. 1 described above except for configurations of color filters 910 and 920 and a light blocking layer 930. Accordingly, the same reference numerals are assigned to the same configurations, and hereinafter, only different configurations will be described.

As shown in FIG. 7, the color filters 910 and 920 are disposed on the encapsulation layer 650.

The color filters 910 and 920 include a first color filter 910 and a second color filter 920.

The first color filter 910 may be formed of a magenta color filter. The first color filter 910 may transmit red (R) light and blue (B) light and absorb green (G) light. For example, the first color filter 810 may absorb green (G) light in a range of 500 nm to 600 nm.

The first color filter 910 may overlap a blue sub-pixel (B sub-pixel) and a red sub-pixel (R sub-pixel). The first color filter 910 may overlap an entire area of the blue sub-pixel (B sub-pixel) and an entire area of the red sub-pixel (R sub-pixel). The first color filter 910 may overlap a blue light emitting area B-EA and a red light emitting area R-EA. The first color filter 910 may overlap the entire blue light emitting area B-EA and the entire red light emitting area R-EA.

Accordingly, blue (B) light emitted from the third light emitting layer 530 in the blue light emitting area B-EA may pass through the first color filter 910, and thus blue (B) light may be emitted from the blue sub-pixel (B sub-pixel). Furthermore, red (R) light emitted from the first light emitting layer 510 in the red light emitting area R-EA may pass through the first color filter 810, so that red (R) light may be emitted from the red sub-pixel (G sub-pixel)

The first color filter 910 may overlap a boundary area between the blue sub-pixel (B sub-pixel) and the red sub-pixel (R sub-pixel). The first color filter 910 may overlap the entire boundary area between the blue sub-pixel (B sub-pixel) and the red sub-pixel (R sub-pixel). The first color filter 910 may overlap the boundary area between the blue light emitting area B-EA and the red light emitting area R-EA. The first color filter 910 may overlap the entire boundary area between the blue light emitting area B-EA and the red light emitting area R-EA. The first color filter 910 may overlap an entire area of the bank 450 disposed in the boundary area between the blue light emitting area B-EA and the red light emitting area R-EA.

Accordingly, the blue (B) light emitted from the third light emitting layer 530 of the blue light emitting area B-EA may be emitted to the boundary area between the blue sub-pixel (B sub-pixel) and the red sub-pixel (R sub-pixel), and the red (R) light emitted from the first light emitting layer 510 of the red light emitting area R-EA may be emitted to the boundary area between the blue sub-pixel (B sub-pixel) and the red sub-pixel (R sub-pixel), and thus luminance characteristics according to the viewing angle may be improved.

In addition, the first color filter 910 may overlap a portion of a boundary area between the red sub-pixel (R sub-pixel) and the green sub-pixel (G sub-pixel). The first color filter 910 may overlap a portion of a boundary area between the red light emitting area R-EA and the green light emitting area G-EA. The first color filter 910 may overlap a portion of the bank 450 disposed in a boundary area between the red light emitting area R-EA and the green light emitting area G-EA. Accordingly, red (R) light emitted from the first light emitting layer 510 of the red light emitting area R-EA may also be emitted to a boundary area between a red sub-pixel (R sub-pixel) and the green sub-pixel (G sub-pixel), and thus luminance characteristics according to the viewing angle may be improved.

In addition, the first color filter 910 may overlap a portion of a boundary area between the green sub-pixel (G sub-pixel) and the blue sub-pixel (B sub-pixel). The first color filter 910 may overlap a portion of a boundary area between the green light emitting area G-EA and the blue light emitting area B-EA. The first color filter 910 may overlap a portion of the bank 450 disposed in a boundary area between the green light emitting area G-EA and the blue light emitting area B-EA. Accordingly, blue (B) light emitted from the third light emitting layer 530 of the blue light emitting area B-EA may also be emitted to a boundary area between the green sub-pixel (G sub-pixel) and the blue sub-pixel (B sub-pixel), and thus luminance characteristics according to the viewing angle may be improved.

The second color filter 920 is formed of a green color filter. The second color filter 920 absorbs blue (B) light and red (R) light and transmits green (G) light.

The second color filter 920 may overlap the green sub-pixel (G sub-pixel). The second color filter 920 may overlap an entire area of the green sub-pixel (G sub-pixel). The second color filter 920 may overlap a green light emitting area (G-EA) The second color filter 920 may overlap an entire area of the green light emitting area (G-EA). Accordingly, green (G) light emitted from the second light emitting layer 520 of the green light emitting area (G-EA) may pass through the second color filter 920, and thus green (G) light may be emitted from the green sub-pixel (G sub-pixel).

The light blocking layer 930 is disposed in an area between the first color filter 910 and the second color filter 920.

The light blocking layer 930 may overlap a portion of a boundary area between the green sub-pixel (G sub-pixel) and the blue sub-pixel (B sub-pixel), and may overlap a portion of a boundary area between the green sub-pixel (G sub-pixel) and the red sub-pixel (R sub-pixel). The light blocking layer 930 may overlap a portion of a boundary area between the green light emitting area G-EA and the blue light emitting area B-EA, and may overlap a portion of a boundary area between the green light emitting area G-EA and the red light emitting area R-EA.

Accordingly, the light blocking layer 930 may block green (G) light emitted from the second light emitting layer 520 of the green light emitting area (G-EA) from being emitted to the blue sub-pixel (B sub-pixel) or the red sub-pixel (R sub-pixel). In addition, the light blocking layer 930 may block blue (B) light emitted from the third light emitting layer 530 in the blue light emitting area B-EA and red (R) light emitted from the first light emitting layer 510 in the red light emitting area R-EA from being emitted to the green sub-pixel (G sub-pixel).

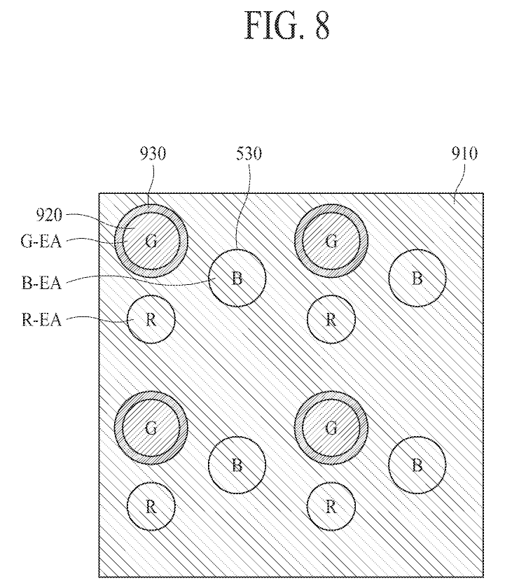

FIG. 8 is a schematic plan view of an electroluminescent display device according to another embodiment of the present disclosure. FIG. 8 is the same as FIG. 2 described above except for the configurations of the color filters 910 and 920 and the light blocking layer 930. Accordingly, the same reference numerals are assigned to the same configurations, and hereinafter, only different configurations will be described.

As shown in FIG. 8, the green light emitting area G-EA is surrounded by the light blocking layer 930. An outer periphery of the light blocking layer 930 has a shape corresponding to an outer periphery of the green light emitting area G-EA.

An inner surface of the light blocking layer 930 may be in contact with the outer periphery of the green light emitting area G-EA. In addition, the outer periphery of the light blocking layer 930 may not be in contact with the red light emitting area R-EA and the blue light emitting area B-EA. The outer periphery of the light blocking layer 930 may be spaced apart from an outer periphery of the red light emitting area R-EA and an outer periphery of the blue light emitting area B-EA by a predetermined distance.

The first color filter 910 may overlap the entire blue light emitting area B-EA, the entire red light emitting area R-EA, the entire boundary area between the blue light emitting area B-EA and the red light emitting area R-EA, a portion of the boundary area between the red light emitting area R-EA and the green light emitting area G-EA, and a portion of the boundary area between the green light emitting area G-EA and the blue light emitting area B-EA. The first color filter 910 transmits blue (B) light and red (R) light and absorbs green (G) light.

The second color filter 920 may overlap the entire area of the green light emitting area G-EA. The second color filter 920 absorbs blue (B) light and red (R) light and transmits green (G) light.

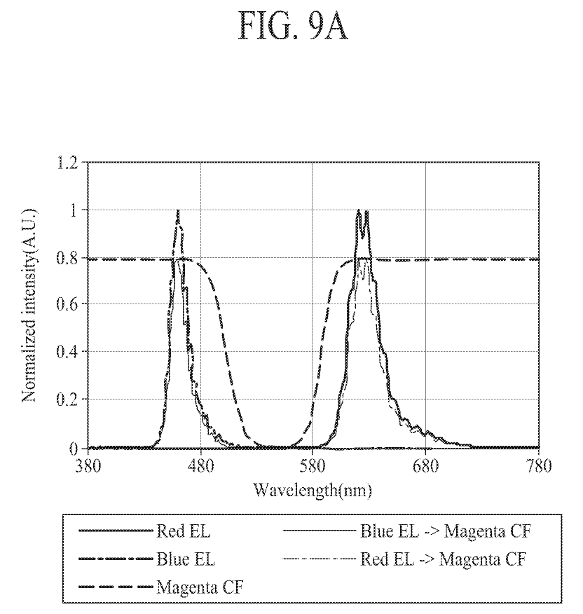

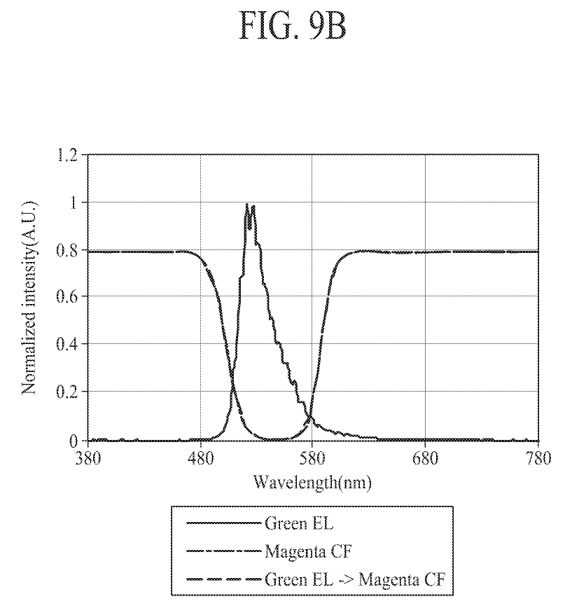

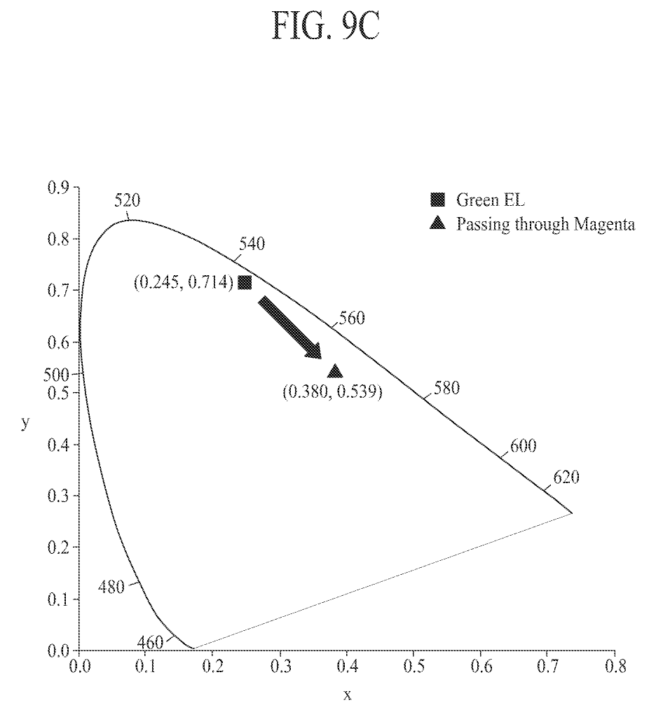

FIG. 9A is a graph showing a light emission spectrum of a blue sub-pixel and a red sub-pixel and a transmission spectrum of a magenta color filter according to another embodiment of the present disclosure, FIG. 9B is a graph showing a light emission spectrum of a green sub-pixel and a transmission spectrum of a magenta color filter according to another embodiment of the present disclosure, and FIG. 9C is a graph showing a state in which a color coordinate of light emitted from a green sub-pixel is changed according to FIG. 9B.

As can be seen from FIG. 9A the blue light emitted from the blue sub-pixel and the red light emitted from the red sub-pixel pass through a magenta color filter. However, since an intensity of a peak of the light transmitted by the magenta color filter is smaller than an intensity of a peak of the blue light emitted from the blue sub-pixel and an intensity of a peak of the red light emitted from the red sub-pixel, an intensity of a peak of the blue light and the red light may be slightly reduced after passing through the magenta color filter.

As shown in FIG. 9B, most of the green light emitted from the green sub-pixel is absorbed by the magenta color filter, but some of the green light can pass through the magenta color filter. And, as shown in FIG. 9C, a color coordinate of some of the green light passing through the magenta color filter can be shifted from an original first color coordinate (Green EL) to a second color coordinate (passing through magenta) which is different from the first color coordinate (Green EL)

Therefore, in FIGS. 7 and 8 described above, if the light blocking layer 930 is not disposed and the first color filter 910 is filled in an area of the light blocking layer 930, the green light emitted from the green sub-pixel (G Sub-pixel) passes through the first color filter 910 and the color coordinates are shifted, which can reduce image quality, so it may not be desirable for the first color filter 910 to fill the area of the light blocking layer 930.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. An electroluminescent display device comprising:
a substrate including a first sub-pixel, a second sub-pixel, and a third sub-pixel;
a first electrode disposed in each of the first sub-pixel, the second sub-pixel, and the third sub-pixel on the substrate;
a light emitting layer including a first light emitting layer on the first electrode of the first sub-pixel, a second light emitting layer on the first electrode of the second sub-pixel, and a third light emitting layer on the first electrode of the third sub-pixel;
a second electrode disposed on the light emitting layer; and
a color filter disposed on the second electrode,
wherein the color filter includes:
a first color filter overlapping the first sub-pixel, the second sub-pixel, and a boundary area between the first sub-pixel and the second sub-pixel, and
a second color filter overlapping the third sub-pixel.

2. The electroluminescent display device of claim 1, wherein the first color filter transmits a light emitted from the first sub-pixel and a light emitted from the second sub-pixel, and absorbs a light emitted from the third sub-pixel, and
wherein the second color filter absorbs the light emitted from the first sub-pixel and the light emitted from the second sub-pixel, and transmits the light emitted from the third sub-pixel.

3. The electroluminescent display device of claim 1, wherein the first sub-pixel is a red sub-pixel that emits a red light, the second sub-pixel is a green sub-pixel that emits a green light, and the third sub-pixel is a blue sub-pixel that emits a blue light, and
wherein the first color filter is a yellow color filter transmitting the red light and the green light and absorbing the blue light in a wavelength range of 380 nm to 500 nm, and the second color filter is a blue color filter.

4. The electroluminescent display device of claim 1, wherein the first sub-pixel is a green sub-pixel that emits a green light, the second sub-pixel is a blue sub-pixel that emits a blue light, and the third sub-pixel is a red sub-pixel that emits a red light, and
wherein the first color filter is a cyan color filter transmitting the green light and the blue light and absorbing the red light in a wavelength range of 600 nm to 780 nm, and the second color filter is a red color filter.

5. The electroluminescent display device of claim 1, wherein the first sub-pixel is a blue sub-pixel that emits a blue light, the second sub-pixel is a red sub-pixel that emits a red light, and the third sub-pixel is a green sub-pixel that emits a green light, and
wherein the first color filter is a magenta color filter transmitting the blue light and the red light and absorbing the green light in a wavelength range of 500 nm to 600 nm, and the second color filter is a green color filter.

6. The electroluminescent display device of claim 1, further comprising a light blocking layer disposed between the first color filter and the second color filter.

7. The electroluminescent display device of claim 1, wherein the first color filter further overlaps a portion of a boundary area between the first sub-pixel and the third sub-pixel and a portion of a boundary area between the second sub-pixel and the third sub-pixel.

8. An electroluminescent display device comprising:
a first light emitting area emitting light of a first color;
a second light emitting area emitting light of a second color;
a third light emitting area emitting light of a third color;
a first color filter overlapping the first light emitting area, the second light emitting area, and a boundary area between the first light emitting area and the second light emitting area; and
a second color filter overlapping the third light emitting area.

9. The electroluminescent display device of claim 8, further comprising a light blocking layer surrounding the third light emitting area.

10. The electroluminescent display device of claim 9, wherein an outer periphery of the light blocking layer has a shape corresponding to an outer periphery of the third light emitting area.

11. The electroluminescent display device of claim 9, wherein an outer periphery of the light blocking layer is not in contact with the first light emitting area or the second light emitting area.

12. The electroluminescent display device of claim 8, wherein the first color filter further overlaps a portion of a boundary area between the first light emitting area and the third light emitting area and a portion of a boundary area between the second light emitting area and the third light emitting area.

13. The electroluminescent display device of claim 8, wherein the first color filter transmits a light emitted in the first light emitting area and a light emitted in the second light emitting area, and absorbs a light emitted in the third light emitting area, and
wherein the second color filter absorbs the light emitted in the first light emitting area and the light emitted in the second light emitting area, and transmits the light emitted in the third light emitting area.

14. The electroluminescent display device of claim 8, wherein the first light emitting area emits a red light, the second light emitting area emits a green light, and the third light emitting area emits a blue light, and
wherein the first color filter is a yellow color filter, and the second color filter is a blue color filter.

15. The electroluminescent display device of claim 8, wherein the first light emitting area emits a green light, the second light emitting area emits a blue light, and the third light emitting area emits a red light, and
wherein the first color filter is a cyan color filter, and the second color filter is a red color filter.

16. The electroluminescent display device of claim 8, wherein the first light emitting area emits a blue light, the second light emitting area emits a red light, and the third light emitting area emits a green light, and
wherein the first color filter is a magenta color filter, and the second color filter is a green color filter.

17. An electroluminescent display device comprising:
a first light-emitting device configured to emit first color light;
a second light-emitting device configured to emit second color light;
a third light-emitting device configured to emit third color light;
a first bank between the first light-emitting device and the second light-emitting device;
a second bank between the first light-emitting device and the third light-emitting device;
a third bank between the second light-emitting device and the third light-emitting device;
a first color filter configured to transmit the first color light and the second color light but absorb the third color light; and
a second color filter configured to transmit the third color light but absorb the first color light and the second color light.

18. The electroluminescent display device of claim 17, wherein the first color filter overlaps the entire first light-emitting device, the entire second light-emitting device, the entire first bank, a first portion of the second bank, and a first portion of the third bank, in a plan view.

19. The electroluminescent display device of claim 17, further comprising a light blocking layer disposed between the first color filter and the second color filter, the light blocking layer overlapping a second portion of the second bank and a second portion of the third bank but not overlapping the first bank, in a plan view.

20. The electroluminescent display device of claim 17, wherein the second color filter overlaps the entire third light-emitting device, a third portion of the second bank, and a third portion of the third bank, in a plan view.
